(19) United States
(12) Patent Application Publication
(10) Pub. No.: US 2011/0177435 A1
(43) Pub. Date: Jul. 21, 2011

(54) Photomasks having sub-lithographic features to prevent undesired wafer patterning

(75) Inventors: Russell T. Herrin, Essex Junction, VT (US); Edmund J. Sprogis, Underhill, VT (US); Anthony K. Stamper, Williston, VT (US)

(73) Assignee: International Business Machines Corporation, Armonk, NY (US)

(21) Appl. No.: 12/690,312

(22) Filed: Jan. 20, 2010

(51) Int. Cl. G03F 1/00

(52) U.S. Cl. 430/5

(57) ABSTRACT

A photomask that is used as a light filter in an exposure system is made of at least one layer of material comprising one or more transparent regions and one or more non-transparent regions. The difference between the transparent regions and the non-transparent regions defines the features that will be illuminated by the exposure system on a photoresist that will be exposed using the exposure system. The features comprise one or more device shapes and at least one sub-lithographic shape that will be exposed upon the photoresist. The sub-lithographic shape has an sub-lithographic shape size that is limited in such a way that the sub-lithographic shape causes a physical change only in a surface of the photoresist. Therefore, because the sub-lithographic shape is so small, it avoids forming an opening through the photoresist after the photoresist is developed and only causes a change on the surface of the photoresist.

### CROSS-REFERENCE TO RELATED APPLICATIONS

This application is related to the following co-pending application filed concurrently herewith by the same Applicant and assigned to the same Assignee entitled “THROUGH SILICON VIA LITHOGRAPHIC ALIGNMENT AND REGISTRATION”, having Attorney Docket No. BUR920080451US1. The complete disclosure of this co-pending application is incorporated herein by reference.

### BACKGROUND

1. Field of the Invention

The present invention relates to exposure systems utilized within photo-lithographic processing, and more specifically, to photomasks that utilizes sub-lithographic features (alignment marks, metrology and process control shapes) that do not interfere with typical design features.

2. Description of the Related Art

When manufacturing integrated circuit devices, it is common to utilize masks that include process control marks that ensure that the mask is in the proper position relative to the substrate. For example, through silicon vias (TSV's) are used for conductively contacting the backside of a ground wafer. Uses of TSV's include grounded emitter SiGe, insulated TSV silicon carriers, etc. For the insulated TSV approach, the TSV is patterned, etched, and filled with a placeholder polysilicon, which is later removed and refilled with a conductor, such as tungsten. This disclosure describes the lithographic marks used for aligning, measuring overlay, and measuring critical dimensions used with integrated circuit technologies, such as insulated and grounded TSV's and other structures.

With insulated TSV's, a TSV opening is patterned and etched prior to deep trench capacitor and/or shallow trench isolation formation. With grounded TSV's, a TSV opening is patterned and etched post transistor formation in the contact module. Problems with the formation of such structures include that extra structures are placed by the mask house somewhat randomly for their mask metrology (critical dimension (cd), cd variability, etc.). If these extra shapes intersect an N-well-P-well boundary, or if they are inside the wrong well, then the extra shapes may cause a high resistance short path which will degrade yield or reliability.

An etching mask is used to etch out the sacrificial polysilicon from the TSV. The placeholder material removal process is performed with a mixture of isotropic (wet) and anisotropic (dry) etching. If the etching mask shape falls over crystalline silicon, then large cavities will be etched into the silicon. Such cavities can destroy underlying structures. Such extra structures can also exacerbate wafer breakage issues due to alignment of the TSV with the crystal plane.

### SUMMARY

One embodiment herein comprises a photomask that is used as a light filter in an exposure system. The photomask is made of at least one layer of material comprising one or more transparent regions and one or more non-transparent regions. The difference between the transparent regions and the non-transparent regions defines the features that will be illuminated by the exposure system on a photoresist that will be exposed using the exposure system.

The features comprise one or more device shapes and at least one sub-lithographic shapes that will be exposed upon the photoresist. The sub-lithographic shape has an sub-lithographic shape size that is limited in such a way that the sub-lithographic shape causes a physical change only in a surface of the photoresist. Therefore, because the sub-lithographic shape is so small, it avoids forming an opening through the photoresist after the photoresist is developed and only causes a change on the surface of the photoresist.

The photoresist becomes an etching mask after the photoresist is developed and the device shapes are transferred to a second layer underlying the etching mask during an etching process that uses the etching mask. Again, the sub-lithographic shape avoids being transferred to the second layer because of the sub-lithographic shape size. To the contrary, the device shapes have one or more device shape sizes. These “device shape sizes” are large enough that the device shapes form one or more openings through the photoresist after the photoresist is developed. The sub-lithographic shape size is smaller than all of the device shapes.

Further, the photomask has a device region and a kerf region surrounding the device region. The device shapes are positioned only in the device region; however, because the sub-lithographic shape is so small, the sub-lithographic shape can be positioned in the kerf region or the device region.

In another embodiment, the photomask is again made of at least one layer of material comprising one or more transparent regions and one or more non-transparent regions. In this embodiment, the features also comprise one or more device shapes and at least one sub-lithographic shape that will be exposed upon the photoresist. However, here the sub-lithographic shape has a sub-lithographic shape size that is limited in such a way that the sub-lithographic shape causes a smaller physical change in the photoresist after the photoresist is developed relative to a change caused by the device shapes after the photoresist is developed. Thus, the device shape sizes cause deeper openings in the second layer underlying the photoresist relative to openings caused by the sub-lithographic shape size. Also, the sub-lithographic shape is positioned a predetermined distance from other alignment marks that will appear on previous or subsequent photomasks (relative to the same location within the exposure system) such that a position of the sub-lithographic shape avoids dishing effects from occurring with the adjacent sub-lithographic shapes in surfaces patterned and planarized using the etching mask.

Another embodiment comprises a series of photomasks that function as light filters in an exposure system. The series of photomasks include a first photomask, a second photomask, a third photomask, etc., that will be used during different exposure steps during an overall exposure process.

The first photomask comprises at least one first layer of material that has one or more first transparent regions and one or more first non-transparent regions. The first features again comprise one or more first device shapes and at least one first sub-lithographic shape. The first sub-lithographic shape has a first sub-lithographic shape size that is limited such that the first sub-lithographic shape causes a physical change only in a surface of the photoresist and such that the first sub-lithographic shape avoids forming an opening through the photoresist after the photoresist is developed.

The second photomask will be exposed after the first photomask is exposed. The second photomask comprises at least one second layer of material comprising one or more second transparent regions and one or more second non-transparent regions. The second features comprise at least one blocking shape. The blocking shape is positioned at a different location than the first sub-lithographic shape relative to the same point within exposure system.

The third photomask will be exposed after the second photomask is exposed. The third photomask comprises at least one third layer of material comprising one or more third transparent regions and one or more third non-transparent regions. The third features comprise one or more third device shapes and at least one third sub-lithographic shape. The third sub-lithographic shape is positioned at the same location as the blocking shape relative to the same point within the exposure system.

In this series of photomasks embodiment, the photoresist(s) becomes an etching mask(s) after the photoresist is developed. The first device shapes and the third device shapes are transferred to a fourth layer underlying the etching mask during an etching process that uses the etching mask. The first sub-lithographic shape avoids being transferred to the fourth layer based on the sub-lithographic shape size. Also, the blocking shape forms a blocking feature on the fourth layer that prevents the third sub-lithographic shape from being patterned into the fourth layer.

The first device shapes and the third device shapes have one or more device shape sizes that are large enough such that the device shapes form one or more openings through the photoresist after the photoresist is developed. However, the first sub-lithographic shape size is smaller than a third sub-lithographic shape size of the third sub-lithographic shape.

The first photomask, the second photomask, and the third photomask each comprise a device region and a kerf region surrounding the device region. The first device shapes and the third device shapes are positioned in the device region, while the first sub-lithographic shape, the blocking shape, and the third sub-lithographic shape are positioned in the kerf region.

Further, the first sub-lithographic shape is positioned a predetermined distance from the third alignment marks on other photomask (relative to the same point within the exposure system) such that a position of the first sub-lithographic shape avoids dishing effects from occurring with the third sub-lithographic shape in surfaces patterned and planarized using the third photomask.

An additional embodiment is again a photomask that comprises a light filter in an exposure system. This photomask also has at least one layer of material comprising one or more transparent regions and one or more non-transparent regions. The difference between the transparent regions and the non-transparent regions defines features that will be illuminated by the exposure system on a photoresist exposed using the exposure system. In this embodiment, the features comprise one or more device shapes and at least one sub-lithographic shape, where the sub-lithographic shape comprises an outline shape.

This “outline shape” comprises at least two outline features (of the previously mentioned features) separated from one another by a distance smaller than sizes of the device shapes. More specifically, the outline features comprise four outline features forming two crossing lines.

### BRIEF DESCRIPTION OF THE SEVERAL VIEWS OF THE DRAWINGS

The embodiments of the invention will be better understood from the following detailed description with reference to the drawings, which are not necessarily drawing to scale and in which:

FIG. 1 is a flow chart illustrating method embodiments herein;

FIG. 2 is a schematic cross-sectional diagram of an integrated circuit structure according to embodiments herein;

FIG. 3 is a schematic cross-sectional diagram of an integrated circuit structure according to embodiments herein;

FIG. 4 is a schematic cross-sectional diagram of an integrated circuit structure according to embodiments herein;

FIG. 5 is a schematic cross-sectional diagram of an integrated circuit structure according to embodiments herein;

FIG. 6 is a schematic cross-sectional diagram of an integrated circuit structure according to embodiments herein;

FIG. 7 is a schematic cross-sectional diagram of an integrated circuit structure according to embodiments herein;

FIG. 8 is a schematic cross-sectional diagram of an integrated circuit structure according to embodiments herein;

FIG. 9 is a schematic cross-sectional diagram of an integrated circuit structure according to embodiments herein;

FIG. 10 is a schematic cross-sectional diagram of an integrated circuit structure according to embodiments herein;

FIG. 11 is a schematic top-view diagram of a process control mark according to embodiments herein;

FIG. 12 is a schematic cross-sectional diagram of an integrated circuit structure according to embodiments herein;

FIG. 13 is a schematic cross-sectional diagram of an integrated circuit structure according to embodiments herein;

FIG. 14 is a schematic cross-sectional diagram of an integrated circuit structure according to embodiments herein;

FIG. 15 is a schematic cross-sectional diagram of an integrated circuit structure according to embodiments herein;

FIG. 16 is a schematic cross-sectional diagram of an integrated circuit structure according to embodiments herein;

FIG. 17 is a schematic cross-sectional diagram of an integrated circuit structure according to embodiments herein;

FIG. 18 is a schematic cross-sectional diagram of an integrated circuit structure according to embodiments herein;

FIG. 19 is a schematic cross-sectional diagram of an integrated circuit structure according to embodiments herein;

FIG. 20a is a schematic diagram of a photomask utilized by embodiments herein;

FIG. 20b is a schematic diagram of a photomask utilized by embodiments herein;

FIG. 21a is a schematic diagram of a photomask utilized by embodiments herein;

FIG. 21b is a schematic diagram of a photomask utilized by embodiments herein;

FIG. 22a is a schematic diagram of a photomask utilized by embodiments herein;

FIG. 22b is a schematic diagram of a photomask utilized by embodiments herein;

FIG. 22c is a schematic diagram of a photomask utilized by embodiments herein;

FIG. 23a is a schematic diagram of a photomask utilized by embodiments herein;

FIG. 23b is a schematic diagram of a photomask utilized by embodiments herein;

FIG. 24a is a schematic diagram of a photomask utilized by embodiments herein;

FIG. 24b is a schematic diagram of a photomask utilized by embodiments herein;

FIG. 25a is a schematic diagram of a photomask utilized by embodiments herein; and

FIG. 25b is a schematic diagram of a photomask utilized by embodiments herein.

### DETAILED DESCRIPTION

The embodiments of the invention and the various features and advantageous details thereof are explained more fully with reference to the non-limiting examples that are illustrated in the accompanying drawings and detailed in the following description.

Chip process control marks are added during wafer processing to allow proper alignment when creating the different integrated circuit structures. It is necessary to have symmetry for wafer frontside/backside processing. An integrated circuit chip needs to either be centered in 0,0 on wafer, or the chip corner needs to be centered to allow for X-Y minoring of the wafer front/backside step plan.

As mentioned above the various process control marks utilized can create extra shapes and if these extra shapes intersect an N-well-P-well boundary, or if they are inside the wrong well, then the extra shapes may cause a high resistance or short path which will degrade yield or reliability. These extra shapes can also exacerbate wafer breakage issues due to alignment of the TSV with the crystal plane of the substrate. Therefore, embodiments herein use shapes for mask alignment and mask inspection which can be sub-lithographic, and which do not extend fully through the mask, so that the shapes will not print on the substrate. The term “sub-lithographic” means that the opening in the mask is smaller than the minimum size feature allowed by the previously established lithographic ground rules for the structure being manufactured and will not allow access to the underlying substrate (even if the opening is formed completely through the mask). For example, if a set of lithographic parameters has a minimum ground rule of 3 um and a 4 um thick photoresist, a sub-lithographic feature would only be a fraction (0.5; 0.25; 0.1; etc.) of the minimum ground rule opening such as a 0.4 um width opening.

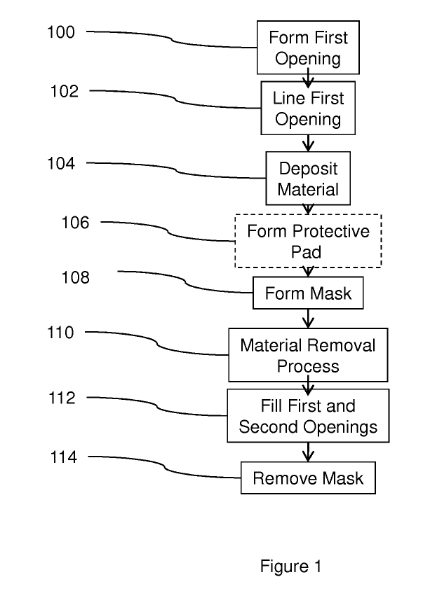

As shown in flowchart form in FIG. 1, in item 100 one exemplary method herein forms a first opening in a substrate (such as silicon substrate) and then, in item 102, lines the first opening with a protective layer (such as an oxide liner). Then, in item 104, the method deposits a material (such as a polysilicon material) into the first opening. In some embodiments, the method can form a one or more structures (such as a protective pad, capacitors, transistors, etc.) on the silicon substrate (as shown in item 106).

The methods also form the protective material (such as an organic photoresist mask) over the silicon substrate in item 108. The organic photoresist mask includes a sub-lithographic process control mark and a second opening. The second opening is above, and aligned with, the first opening. In item 110, the method performs a material removal process by, for example, performing reactive ion etching to remove the polysilicon material from the first opening through the second opening in the organic photoresist mask.

A shown in item 112, the method can fill the first and second openings with an appropriate conductive material and then remove the mask (item 114) to form a conductive structure extending above the first opening.

If a protective structure is utilized, the process control mark is above, and aligned with, the protective structure. With the embodiments herein, the process control marks can be formed above a kerf region of the silicon substrate or can be formed above other regions of the substrate.

Further, the process control mark can comprise a recess within the organic photoresist mask that extends only partially through the organic photoresist mask, such that portions of the silicon substrate below the process control mark are not affected by the reactive ion etching. In such embodiments, the process control mark can be sub-lithographic and does not extend completely through the organic photoresist mask but instead only extends partially through the mask. Thus, the organic photoresist mask protects portions of the silicon substrate that are not beneath the second opening.

The reactive ion etching comprises a process that would damage the silicon substrate. The organic photoresist mask, the oxide liner, and the protective structure protect the silicon substrate from such reactive ion etching.

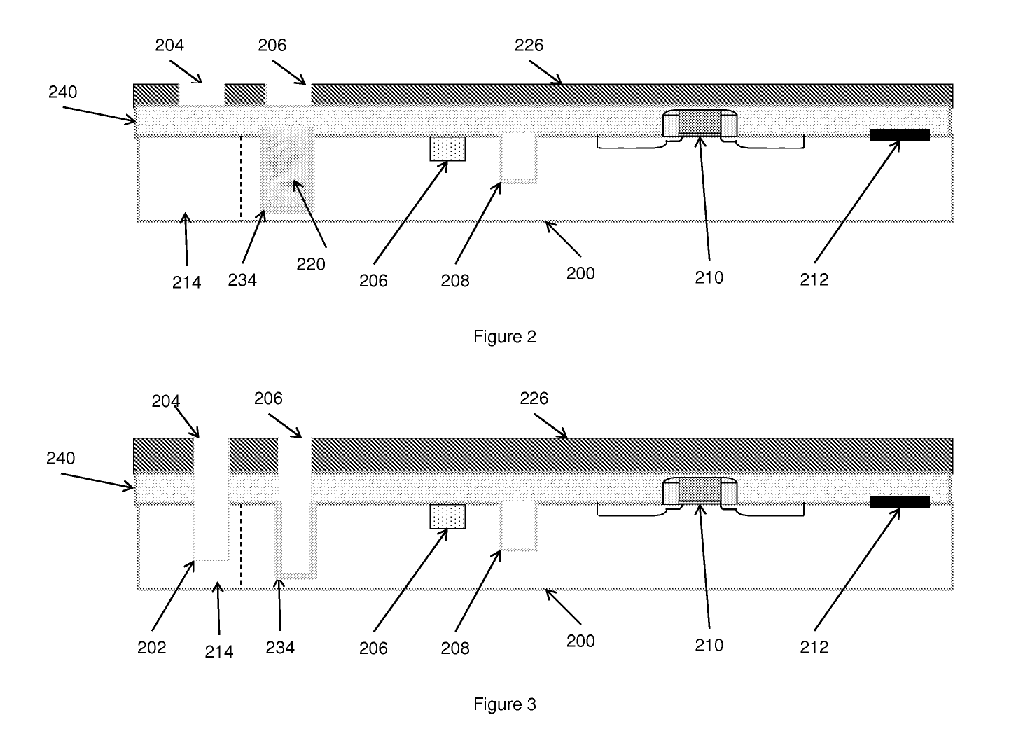

FIG. 2 illustrates a cross-sectional view of a partially completed integrated circuit structure that is formed within the substrate 200 (such as a silicon substrate). The structure includes a kerf region 214 that will be removed when the substrate 200 is diced into chips. In addition, an opening 234 has been formed within the substrate 200. The process of forming openings within substrates is well known to those ordinarily skilled in the art (e.g., see U.S. Pat. Nos. 4,978,419 and 7,485,965, the complete disclosures of which are incorporated herein by reference) and a detailed discussion of such processes is not included herein. All the openings mentioned in this disclosure can be formed by any conventionally known method (or methods developed in the future) such as etching substrate material through a patterned mask.

The opening 234 has been lined with a liner (oxide, a nitride, etc.) and filled with a placeholder material 220 such as polysilicon. Again, the processes of lining openings and filling openings with material are well-known to those ordinarily skilled in the art (e.g., see U.S. Pat. No. 6,521,493, the complete disclosure of which is incorporated herein by reference) and a detailed discussion of such processes is not included herein. The lining material can be formed, for example, by growing an oxide or nitride on the sidewalls of the opening. In addition, material can be grown or placed within the opening using any conventionally known process such as spin-on processing, sputtering, vapor depositions, etc. The opening 234 will eventually become the through silicon via (TSV).

Item 206 represents a shallow trench isolation region within the substrate 200. The processes for forming said structures are well-known to those ordinarily skilled in the art (e.g., see U.S. Pat. No. 7,394,131, the complete disclosure of which is incorporated herein by reference in a detailed discussion of the same is not include herein). Shallow trench isolation regions can be formed by removing a portion of the substrate and replacing it with an insulator material such as an oxide.

Item 208 represents a deep trench capacitor. Again, the processes for forming such structures are well-known to those ordinarily skilled in the art (e.g., see U.S. Pat. No. 6,809,005, the complete disclosure of which is incorporated herein by reference) and a detailed discussion of the processes for forming deep trench capacitors is not included herein. Generally, deep trench capacitors can be formed by patterning a trench within the substrate, lining the trench with an insulator (oxide, nitride, etc.) and then filling the lined trench with a conductor.

Item 210 represents a transistor (such as a field effect transistor (FET)). Transistors are also well known structures that are formed according to methods well known by those ordinarily skilled in the art (e.g., see U.S. Pat. No. 7,510,916, the complete disclosure of which is incorporated herein by reference) and a detailed discussion of transistor formation is not included herein. Transistors can be formed generally by doping a channel region within the substrate, forming a gate oxide above the channel region, forming a gate conductor above the channel region, and forming source and drain regions within the substrate on opposite sides of the gate conductor.

Item 212 represents a silicide block which is utilized to prevent silicide formation in areas of the substrate 200. Silicide blocks are also well known structures that are formed according to methods well known by those ordinarily skilled in the art and a detailed discussion of the formation process for silicide blocks is not included herein. Generally, silicide blocks can be formed by patterning (again using masks and other similar structures) material such as nitrides, oxides, etc. on the surface in lieu of the substrate 200.

Once such an intermediate structure is created, it may be desirable to complete the through silicon via structure 234 by removing the polysilicon placeholder 220 and forming a conductor that extends from the through silicon via 234. One manner in which this could be accomplished is by etching the placeholder material 220 through a photoresist mask formed on top of an insulator or dielectric layer 240.

One such photoresist mask is shown as item 222 in FIG. 2. The mask 222 includes an alignment opening (or process control mark) 204 that is positioned above (with respect to the top of the substrate 200) the kerf region 214 and an opening 206 that is positioned above the first opening 234. The process control mark 204 is necessary to properly align the opening 206 above the opening 234.

FIG. 3 illustrates the structure after the material removal process (e.g., reactive ion etching) has removed the placeholder 220 from the opening 234. This removal process also etched an opening 202 into the substrate. This opening 202 is formed below the process control mark 204 can cause some undesirable problems including unintended substrate breakage, electrical shorts, etc. In addition, if the opening 202 is formed outside the kerf region 214, the opening 202 can interfere with (and potentially destroy) the various other structures shown in FIG. 2. Such openings 202 below process control marks are especially problematic as the aspect ratio of evolving integrated circuit devices makes substrate trenches longer and more narrow.

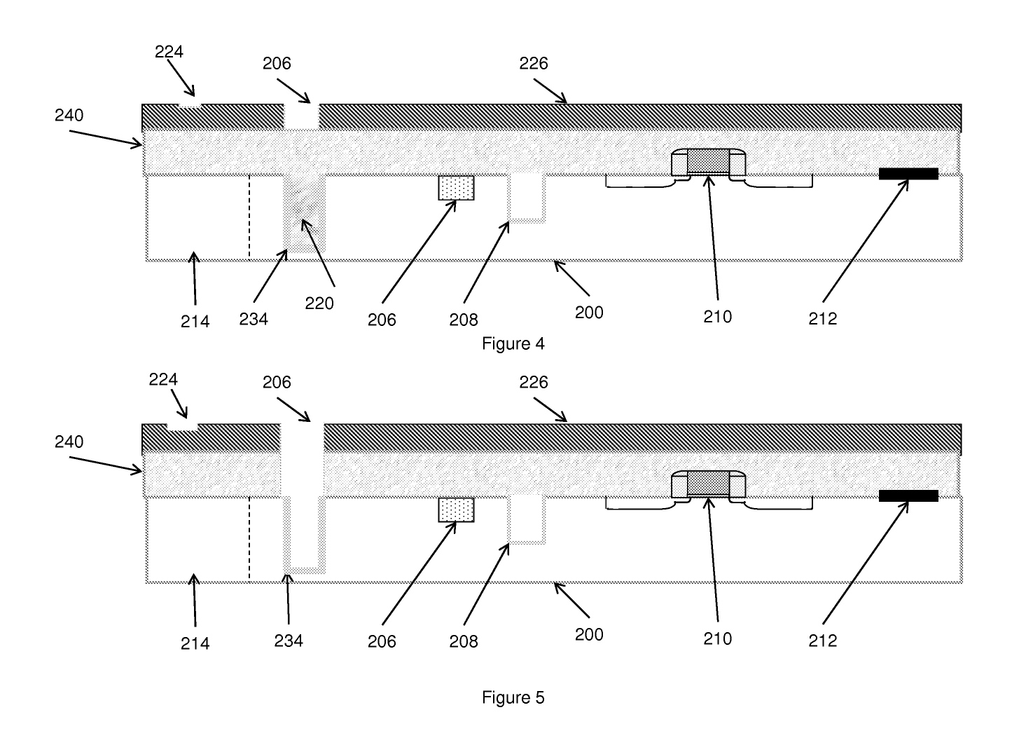

The structure shown in FIG. 4 is similar to that shown in FIGS. 2 and 3; however a different etching mask 226 is utilized that includes a different type of process control mark opening 224. More specifically, the process control mark 224 is sub-lithographic and does not penetrate completely through the mask 226. Instead, mark 224 only penetrates, for example, 25%, 50%, 75% etc. through the mask 226 and the opening 224 does not run completely from the top of the mask 226 to the bottom of the mask 226. Therefore, as shown in FIG. 5, when the material removal process is performed to remove the placeholder 220, no opening is formed in the substrate 200 or dielectric 240 below the process control mark 224 and, possibly only some of the dielectric 240 is removed. Contrast this with the opening 202 that is formed in the substrate in FIG. 3. Therefore, by utilizing an etching mask that includes sub-lithographic process control marks that do not completely pass through the mask, the problems associated with openings formed below process control marks that are described above can be reduced or eliminated

As an alternative to making the process control mark 224 less deep than the non-sub-lithographic process control mark 204 shown in FIGS. 2 and 3, the mask material 226 can be made thicker than the mask material 222. For example, the mask material of the mask 226 can be made 125%, 150%, 175%, 2×, 3×, 4×, thicker than the mask material 222. This potentially allows the process control mark formation process to remain the same and yet still allows the process control marks to not fully penetrate the mask material. Therefore, by either forming the process control mark in a more shallow manner and/or by making the mask material thicker, it is possible to prevent the process control marks from fully penetrating through the entire width of the etching mask material.

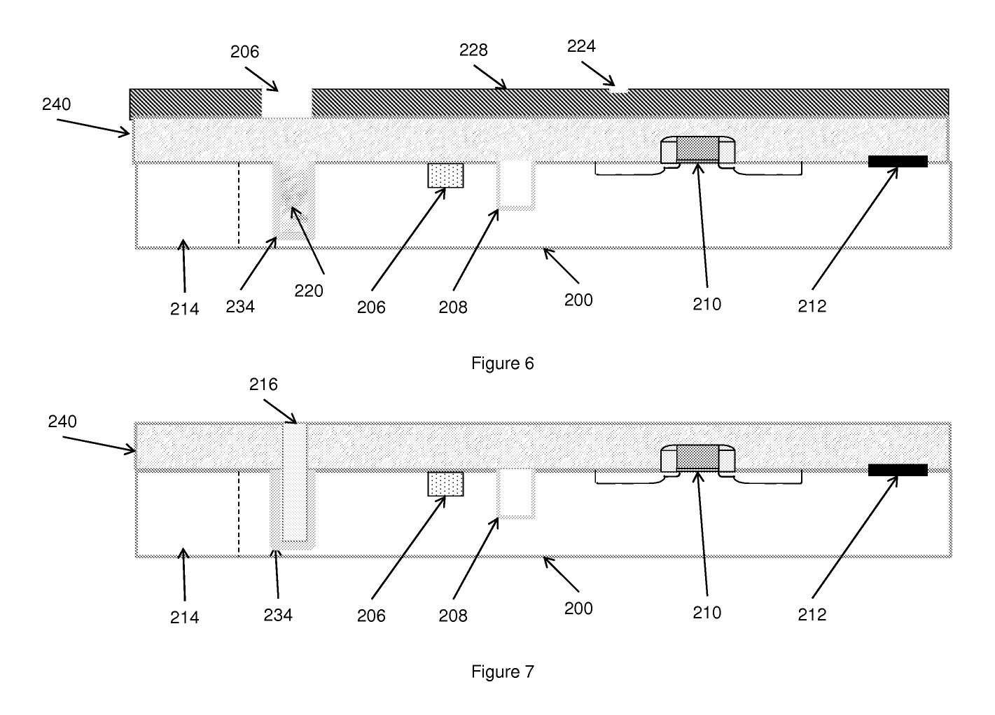

Further, because the process control mark is not formed fully through the etching mask, the process control mark does not need to be placed above the kerf region 214. Therefore, as shown in FIG. 6, it is possible to create a mask 228 that includes a process control mark 224 that is not positioned above the kerf region 214 without causing substantial problems associated with the trench 202, mentioned above.

All of the embodiments herein can form a conductor within the opening 234 to complete the through silicon via structure. Therefore, as shown in FIG. 7, a conductor 216 (tungsten, copper, polysilicon, etc.) can be formed in openings 234, 206 (see FIGS. 3 and 5) and then the etching mask can be removed in a selective material removal process that leaves the conductor 216 within the opening 234 and extending above the substrate 200 into the dielectric 240.

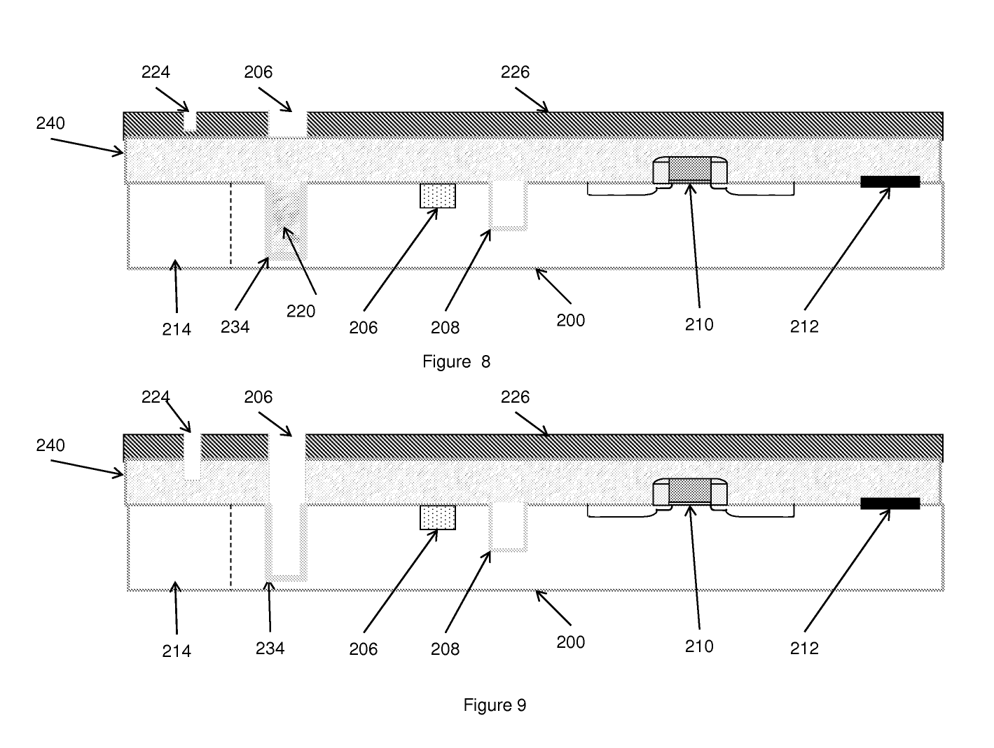

Another embodiment involves designing process control marks that are not sub-lithographic, but that are much smaller than the device structures to be etched using the photomask. An example is shown in FIGS. 8 and 9. The process control mark 224 will be patterned through the photomask 226 and etched in the substrate 200, but to a shallower depth than the other features created by the photomask. Shallower structures are less likely to cause wafer breakage and other problems associated with deeply etched structures in the substrate. This embodiment is useful if the lithographic mark is needed at another level. Marks for measuring how accurately a photomask overlays previous mask structures are an example of such marks.

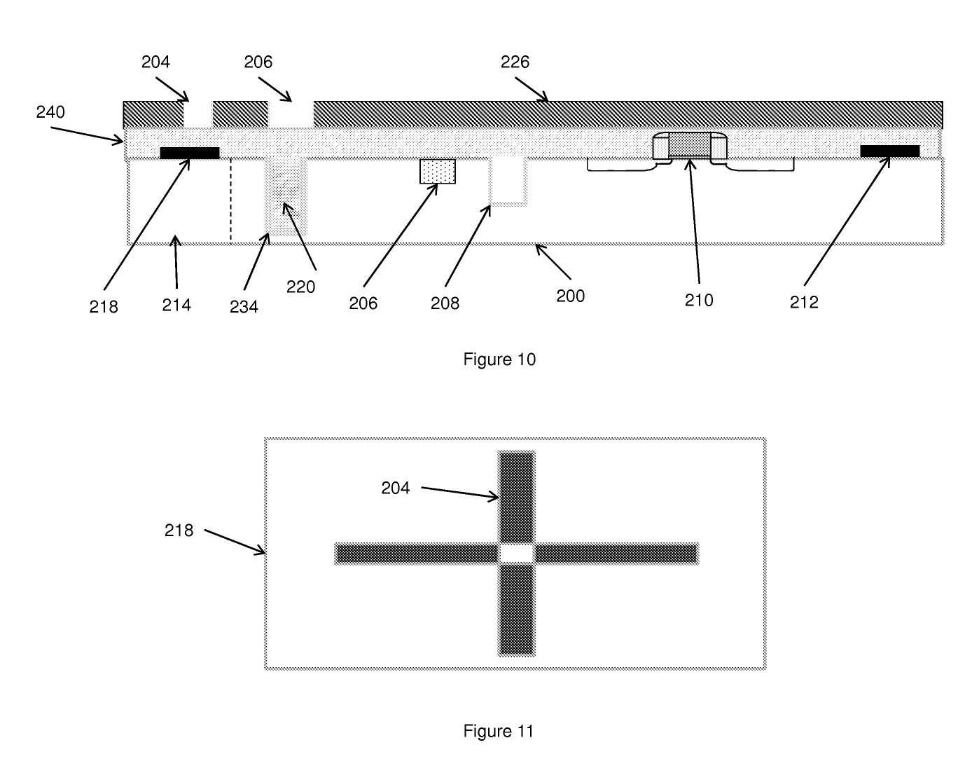

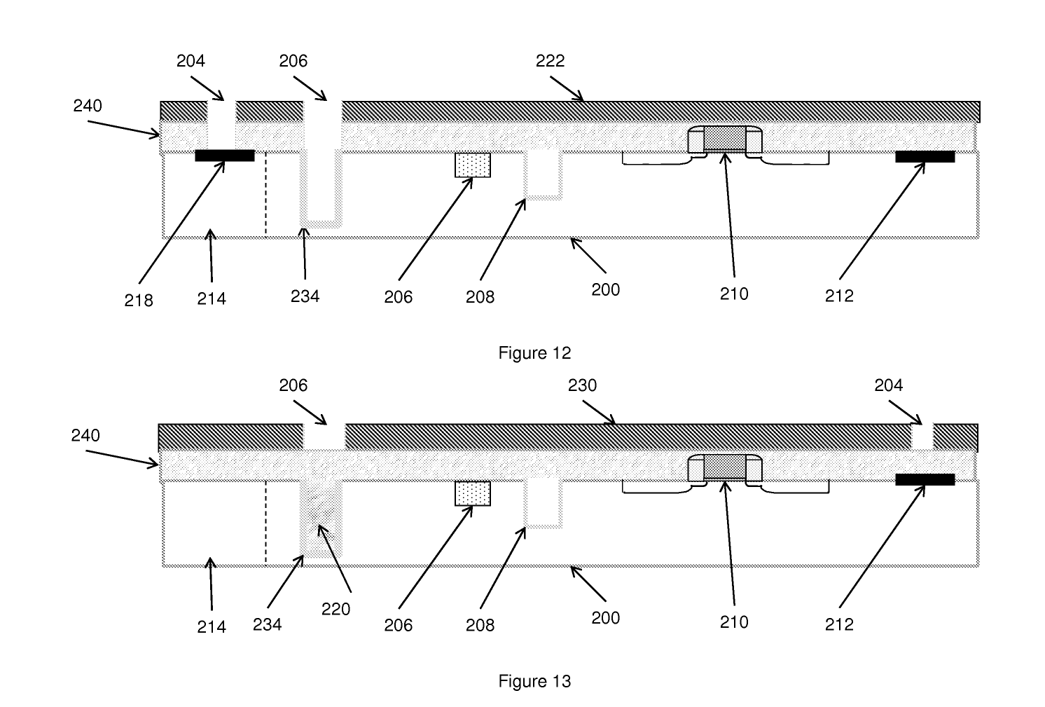

Other embodiments herein can utilize the mask 222 (discussed above) that includes a process control mark opening 234 that extends fully through the mask 222 without damaging the underlying substrate by utilizing protective structures 218 that are positioned below the opening 204, as shown in FIG. 10. FIG. 11 illustrates the top-view of the process control mark 204 as it is positioned over the protective structure 218. As shown in FIG. 12, after the material removal process has removed the polysilicon 220, no trench 202 is formed within the substrate 200 because the protective structure 218 prevented the formation of any such trench.

FIG. 13 illustrates that utilization of protective pads can allow alignment marks 204 to be placed outside of the kerf area without substantial problems associated with trench 202, as described above.

The protective structures 218 can comprise any material that will not be attacked by the process that removes the polysilicon 220. For example, if a reactive ion etching process that attacks silicon is utilized to remove the polysilicon 220, the protective structure can be formed of an oxide, a nitride, etc. The protective structures can be formed using the same processes used to form the silicide breaks 212, discussed above.

In addition, if desired, other structures that will not be affected by the material removal process can be used as protective structures. For example, as shown in FIGS. 12 and 13, the silicide break 212 is utilized as the protective structure.

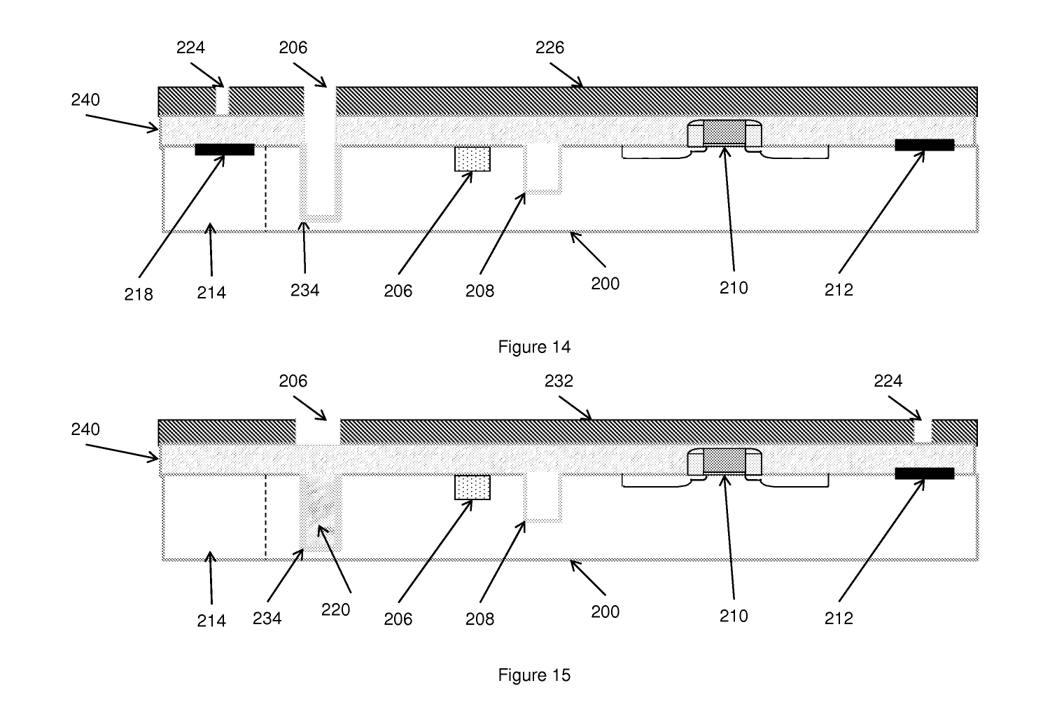

The foregoing concepts can be combined. The protective structure 218 can be positioned below a process control mark 224 that does not extend fully through the etching mask material 226 as shown in FIG. 14. FIG. 15 illustrates that this same structure can be formed outside the kerf region 214 when the silicide break 212 is utilized as a protective structure below the process control mark 224 that does not fully extend through the etching mask material 226.

As mentioned above the various process control marks utilized can create extra shapes and if these extra shapes intersect an N-well-P-well boundary, or if they are inside the wrong well, then the extra shapes may cause a high resistance or short path which will degrade yield or reliability. These extra shapes can also exacerbate wafer breakage issues due to alignment of the TSV with the crystal plane of the substrate. Therefore, embodiments herein use shapes for mask alignment and mask inspection which are sub-lithographic, and which do not extend fully through the mask, so that shapes will not print on the substrate. In such embodiments, the process control mark is sub-lithographic and does not extend completely through the organic photoresist mask but instead only extends partially through the mask. Thus, the organic photoresist mask protects portions of the silicon substrate that are not beneath the second opening.

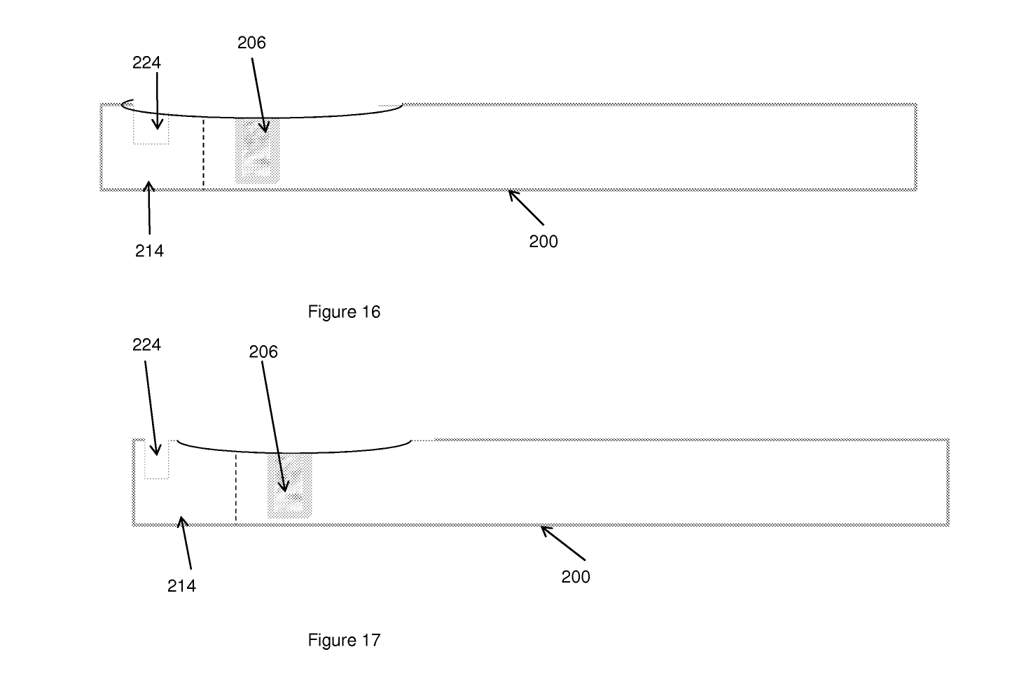

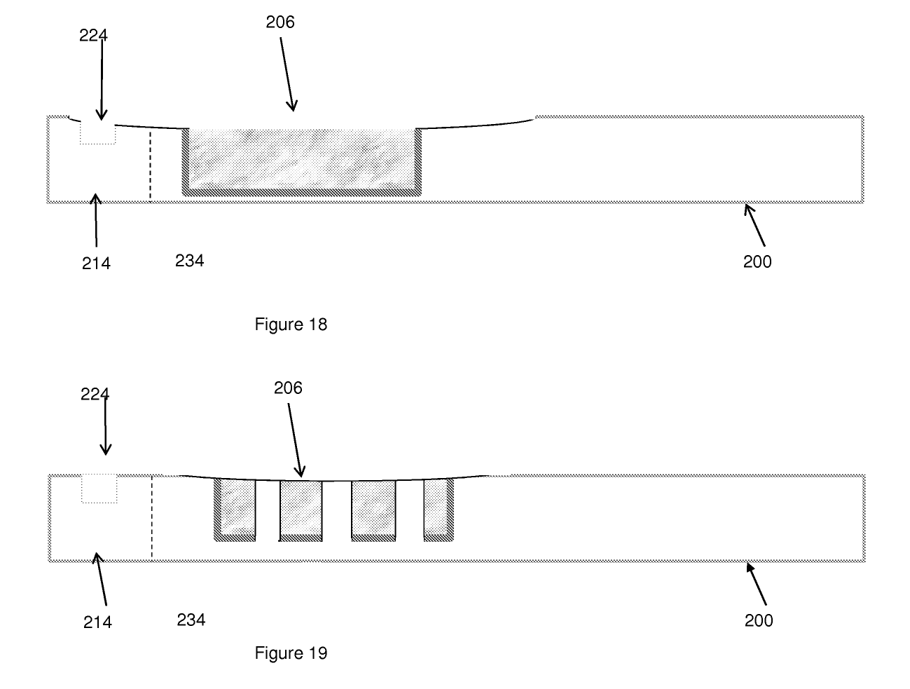

In another embodiment, placement of lithographic structures in the kerf is designed so as to prevent damage to these structures from dishing caused by chemical-mechanical polish of nearby wide or deep structures. Some lithographic marks (e.g., overlay marks) need to be used after the level at which they are etched in the substrate or other film. As shown in FIG. 16, preferential polishing of a material in a large structure, such as material 220 in trench 206 can create dishing, which can damage nearby lithographic marks and render them unusable. Designing the lithographic mark layout to leave sufficient distance between large features and lithographic marks, as shown in FIG. 17, prevents this problem. Adding dummy-shape fill patterns or blocking patterns near critical structures reduces the width of openings or eliminates them. This can also prevents dishing of critical structures. The dishing created by opening 206 in FIG. 18 damages mark 224. Blocking all or a portion of the etch for opening 206 protects mark 224, as shown in FIG. 19.

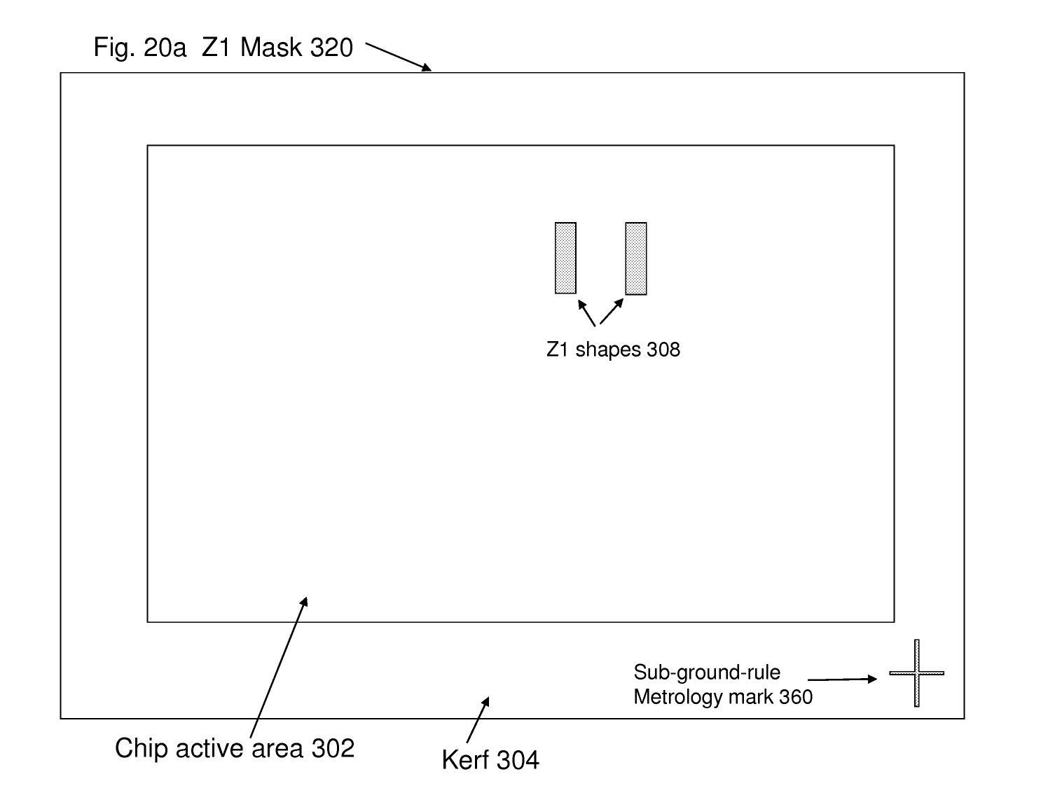

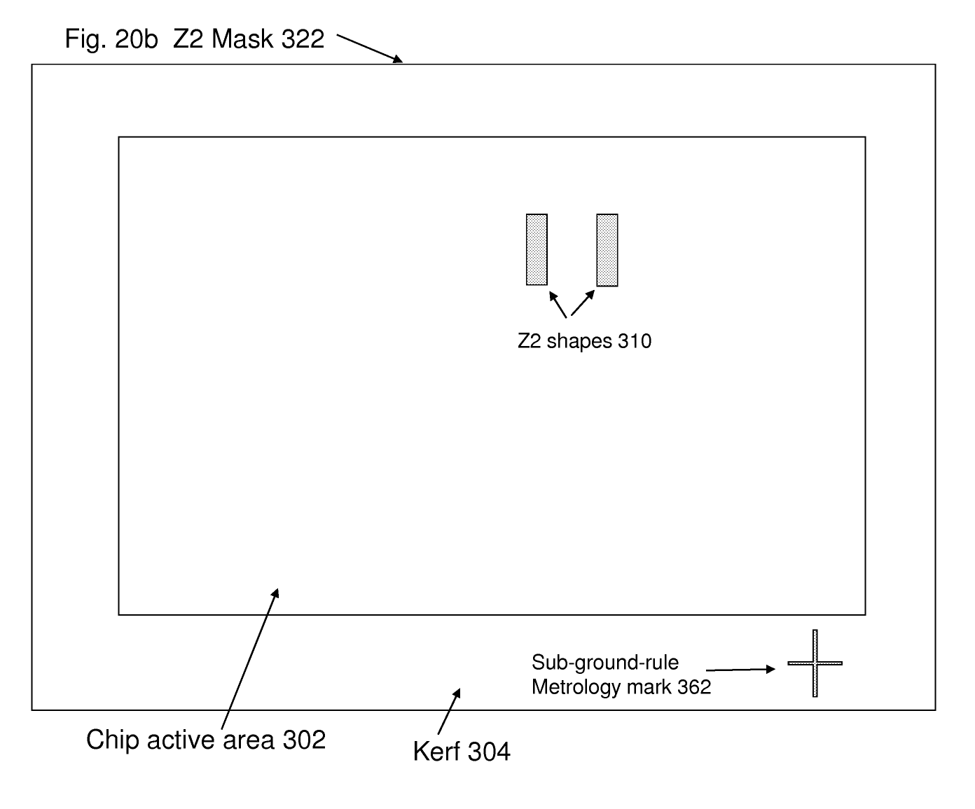

In additional embodiments shown in FIGS. 20a-25b, the photomasks themselves have many unique features. Lithographic photomasks are typically transparent fused silica blanks covered with a pattern defined with a chrome metal absorbing film. A set of photomasks can be made up of up to 20, 30, 50, or more photomasks. Each of the photomasks defines a pattern layer in integrated circuit fabrication and is fed into a photolithography stepper or scanner and individually selected for exposure. In photolithography for the mass production of integrated circuit devices, the more correct term is usually photoreticle or simply reticle.

One photomask 320 according to embodiments herein as shown in FIG. 20a. Such a photomask 320 is used as a light filter in a photolithographic exposure system and is made of at least one layer of material comprising one or more transparent (e.g., fused silica) regions (chip active area 302 and kerf 304) and one or more non-transparent (e.g., chrome) regions (Z1 shapes 308; alignment marks 306). The difference between the transparent regions 302, 304 and the non-transparent regions 308, 306 defines the features that will be illuminated by the exposure system on a photoresist that will be exposed using the exposure system.

The features comprise one or more device shapes 308 and at least one sub-lithographic shape 360 that will be exposed upon, for example, the photoresist 226 shown in FIG. 4. The sub-lithographic shape 360 has a size that is limited in such a way that the sub-lithographic shape 360 causes a physical change only in a surface of the photoresist 226 (opening 224 that is only partially through the photoresist 226 in FIG. 4). Therefore, because the sub-lithographic shape 360 is a sub-ground-rule metrology mark (is too small to lithographically form features according to the system ground rules) it avoids forming an opening through the photoresist after the photoresist is developed and only causes a change on the surface of the photoresist 226 (or a partial opening 224 within the photoresist 226).

As shown in FIG. 5, above, the photoresist becomes an etching mask 226 after the photoresist is developed and the device shapes 308 are transferred to one or more layers 240, 200 (e.g., at least one “second” layer) underlying the etching mask 226 during the etching process (that uses the etching mask 226 that was exposed using the photomask 320). Again, the sub-lithographic shape 360 avoids being transferred to the second layer (200, 240) because of the sub-lithographic shape size.

To the contrary, the device shapes 308 have one or more device shape sizes. These “device shape sizes” are large enough that the device shapes 308 form one or more openings 206 through the photoresist 226 after the photoresist 226 is developed. The sub-lithographic shape size is smaller than all of the device shapes 308.

FIG. 20b illustrates a similar sub-ground-rule alignment mark 362 used with a different mask 322 (e.g., a Z2 mask) that forms Z2 shapes 310. Further, the photomask 322 has a device region 302 and a kerf region 304 surrounding the device region 302. The device shapes 308, 310 are positioned only in the device region 302; however, because the sub-lithographic shape 360 is so small, the sub-lithographic shape 360 can be positioned in the kerf region 304 or the device region 302.

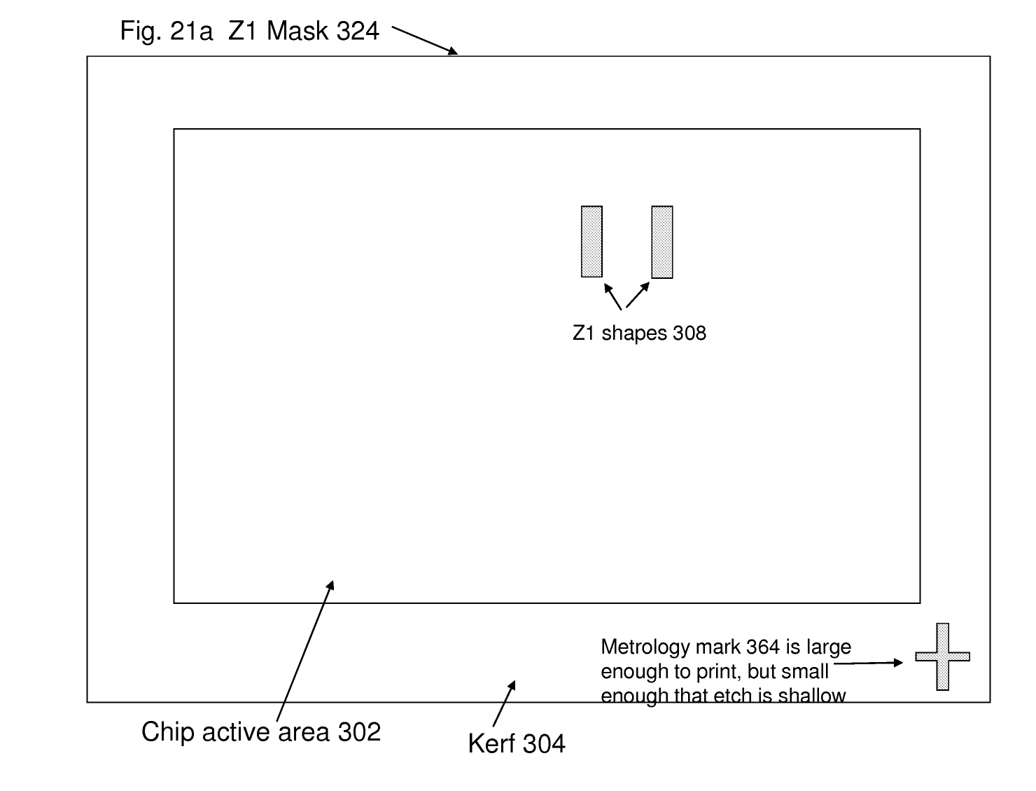

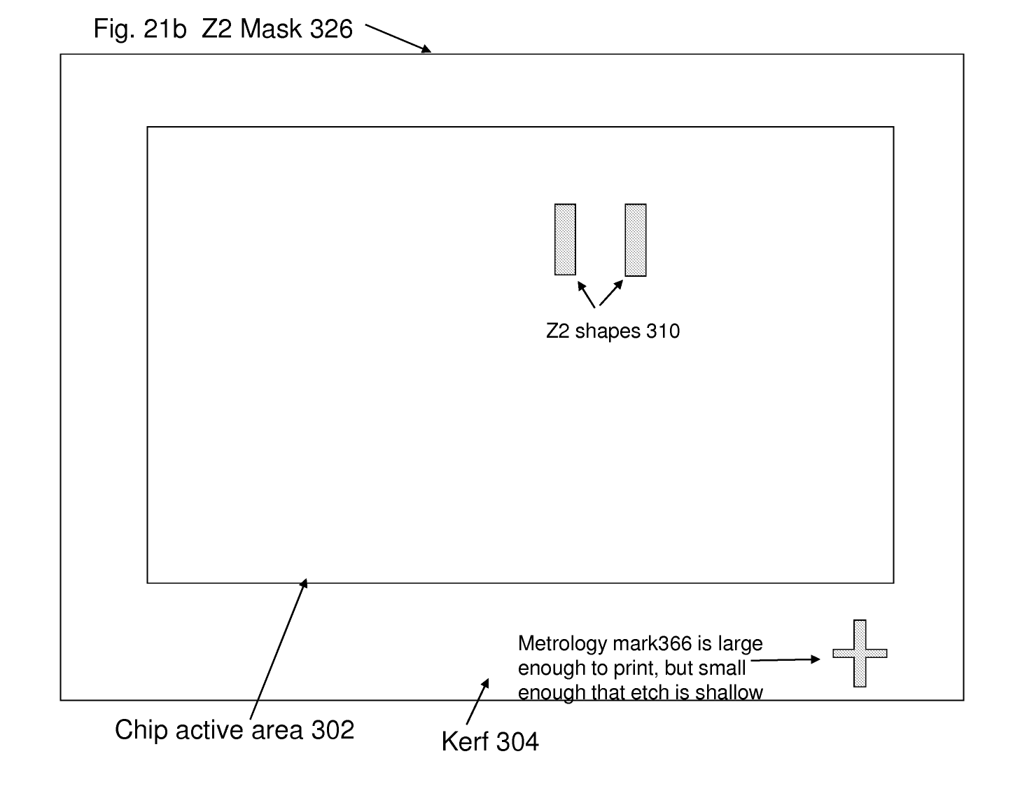

In another embodiment shown in FIGS. 21a and 21b, the photomasks 324, 326 are again made of at least one layer of material comprising one or more transparent regions 302, 304 and one or more non-transparent regions 308, 306. However, here the sub-lithographic shapes 364, 366 have an sub-lithographic shape size that is limited in such a way that the sub-lithographic shape 360 causes a smaller physical change in the photoresist 226 after the photoresist 226 is developed relative to a change caused by the device shapes 308, 310 after the photoresist 226 is developed. Thus, as shown in FIGS. 8 and 9, the device shape sizes cause deeper openings 206 in the second layer (200, 240) underlying the photoresist 226 relative to opening 224 caused by the size of the sub-lithographic shapes 364, 366.

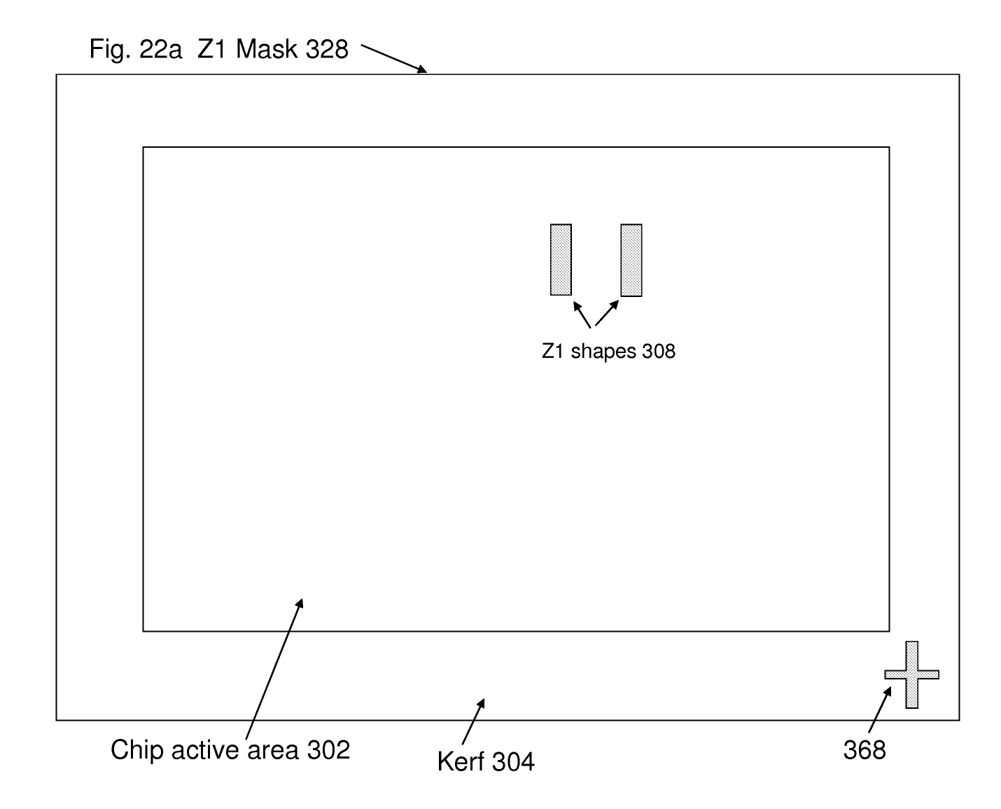

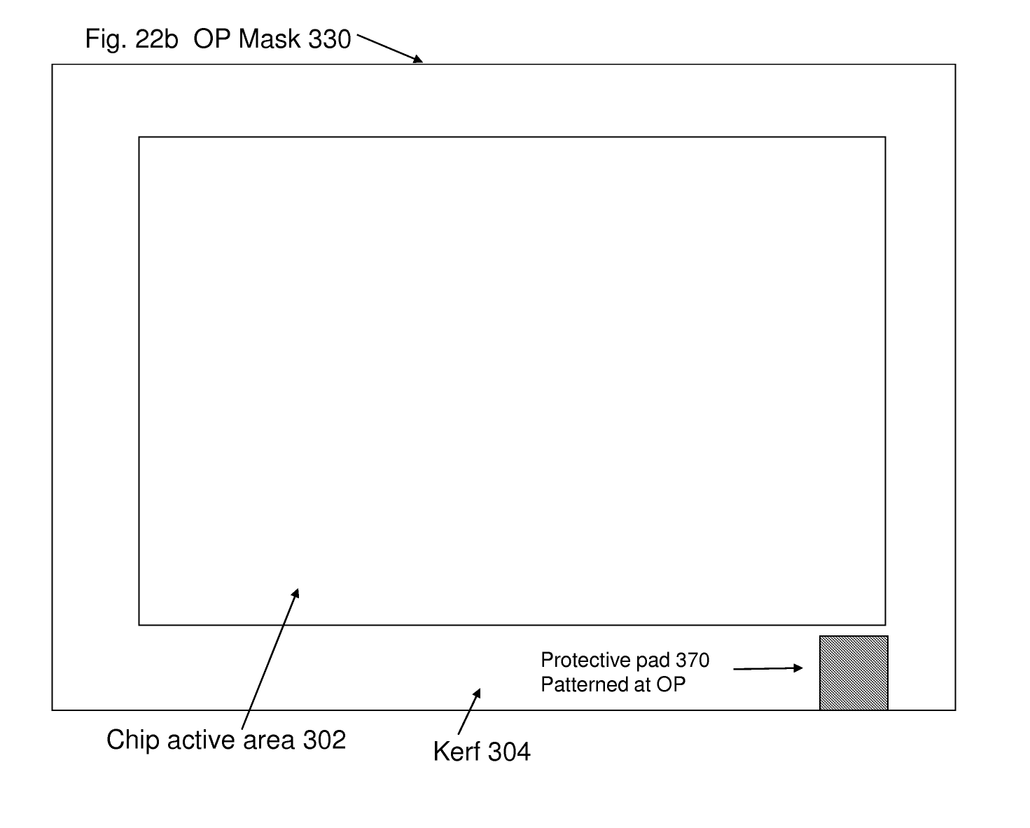

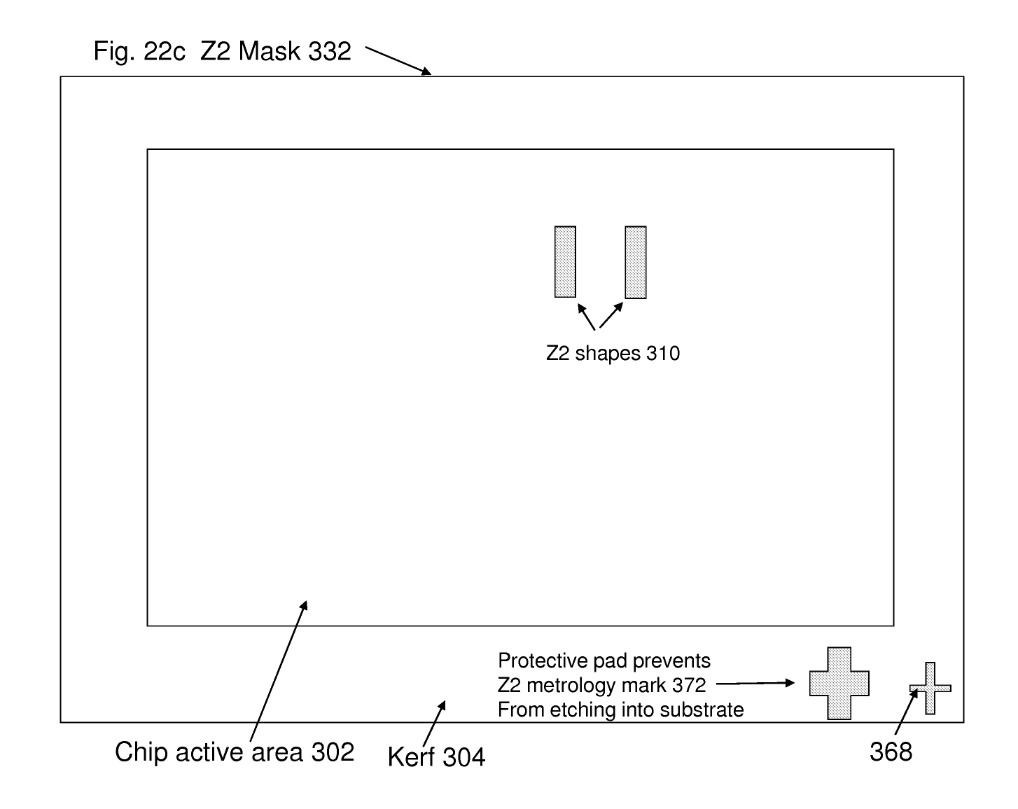

Another embodiment (shown in FIGS. 22a-22c) comprises a series of photomasks 328, 330, 332 that function as light filters in an exposure system. The series of photomasks 328, 330, 332 include a first photomask 328, a second photomask 330, a third photomask 332, etc., that will be used during different exposure steps during an overall exposure process.

The first photomask 328 comprises at least one first layer of material that has one or more first transparent regions 302, 304 and one or more first non-transparent regions 308, 306. Again, the difference between the first transparent regions 302, 304 and the first non-transparent regions 308, 306 defines first features that will be illuminated by the exposure system on a photoresist 226 exposed using the exposure system. The first features again comprise one or more first device shapes 308, 310 and at least one first sub-lithographic shape 368. The first sub-lithographic shape 368 can have a first sub-lithographic shape size that is limited such that the first sub-lithographic shape 368 can cause a physical change only in a surface of the photoresist 226 and such that the first sub-lithographic shape 368 avoids forming an opening through the photoresist 226 after the photoresist 226 is developed. Alternatively, the first sub-lithographic shape 368 may be larger and form a deeper opening in the photoresist.

The second photomask 330 will be exposed after the first photomask 328 is exposed. The second photomask 330 comprises at least one second layer (200, 240) of material comprising one or more second transparent regions 302, 304 and one or more second non-transparent regions 308, 306. Again, the difference between the second transparent regions 302, 304 and the second non-transparent regions 308, 306 defines second features that will be illuminated by the exposure system on the existing photoresist 226 (or a different photoresist 226) exposed using the exposure system. The second features comprise at least one blocking shape 370. The blocking shape 370 is positioned at a different location than the first sub-lithographic shape 368 relative to the same point within exposure system.

The third photomask 332 will be exposed after the second photomask 330 is exposed. The third photomask 332 comprises at least one third layer of material comprising one or more third transparent regions 302, 304 and one or more third non-transparent regions 308, 306, the difference between the third transparent regions 302, 304 and the third non-transparent regions 308, 306 defines third features that will be illuminated by the exposure system on the (same or different) photoresist 226 exposed using the exposure system. The third features comprise one or more third device shapes 308, 310 and at least one third sub-lithographic shape 372. The third sub-lithographic shape 372 is positioned at the same location as the blocking shape 370 (relative to the same point within the exposure system). Note that FIG. 3 also illustrates the position that the sub-lithographic shape 368 had in the mask 328.

In this series of photomasks embodiment, the photoresists becomes etching masks after the photoresists 226 are developed. The first device shapes 308, 310 and the third device shapes 308, 310 are transferred to a fourth layer (e.g., 200) underlying the etching mask 226 during an etching process that uses the etching mask 226 (shown in FIG. 10, discussed above). The first sub-lithographic shape 368 avoids being transferred to the fourth layer based on the sub-lithographic shape size. Also, the blocking shape 370 forms a blocking feature 218 on the fourth layer that prevents the third sub-lithographic shape 372 from being patterned into the fourth layer. This is also illustrated in FIG. 10 where the photoresist that was patterned with the second photomask 330 formed blocking shapes 218. The photoresist 226 (shown in FIG. 10) that was patterned with the third photomask 332 has an sub-lithographic shape opening 204 that is aligned directly above the blocking shape 218. Therefore, as noted above, the underlying layers (e.g., 200) will be protected from any etching process through opening 204 by the blocking shapes 218 that are formed by the second photomask 330 in the series of photomasks.

The first photomask 328, the second photomask 330, and the third photomask 332 each comprise a device region 302 and a kerf region 304 surrounding the device region 302. The first device shapes 308, 310 and the third device shapes 308, 310 are positioned in the device region 302, while the first sub-lithographic shape 368, the blocking shape 370, and the third sub-lithographic shape 372 are positioned in either the device region 302 or the kerf region 304.

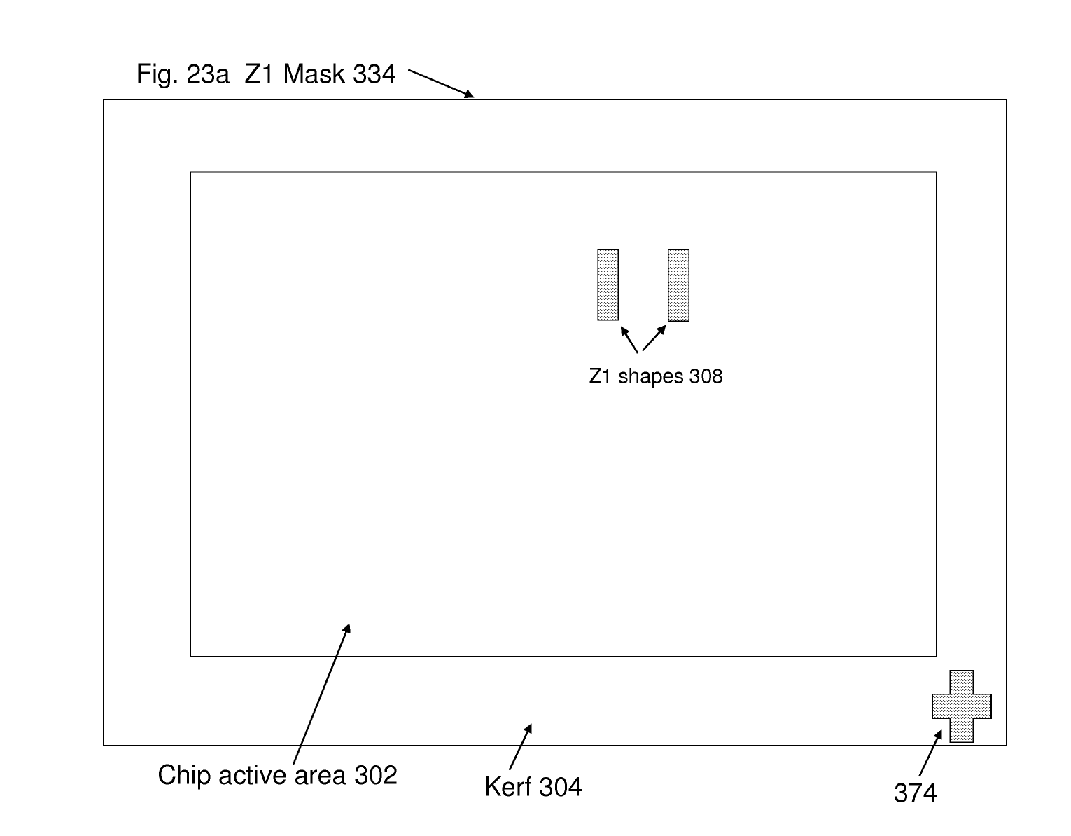

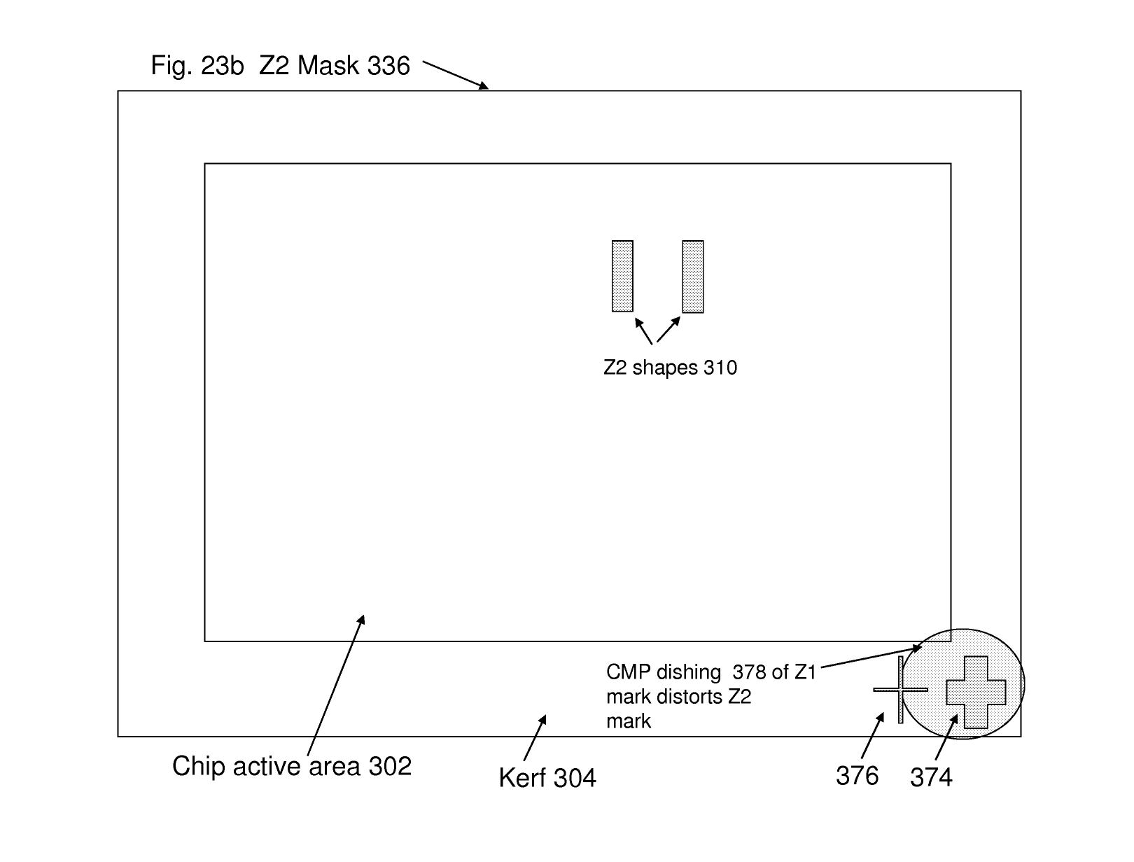

Further in all the embodiments herein, the first and second sub-lithographic shapes can be positioned a predetermined distance from each other on the different photomasks (relative to the same point within the exposure system) such that a position of the first sub-lithographic shape avoids dishing effects from occurring in surfaces patterned and planarized using the third photomask. Such a dishing shape is illustrated as item 378 in FIG. 23b.

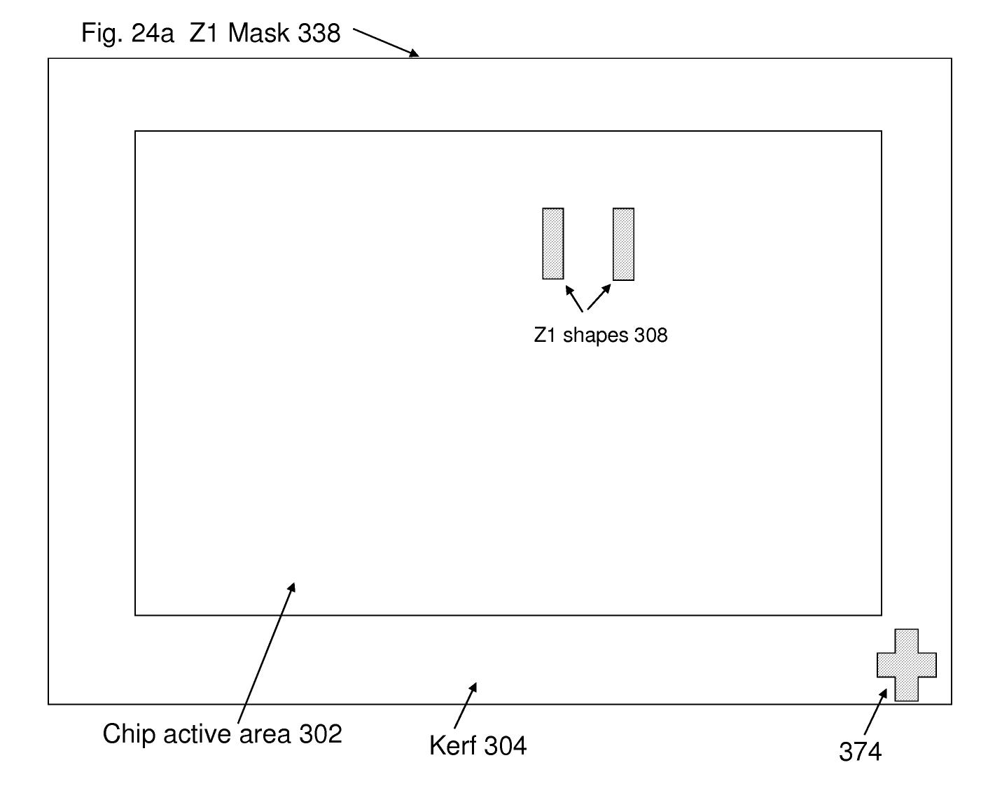

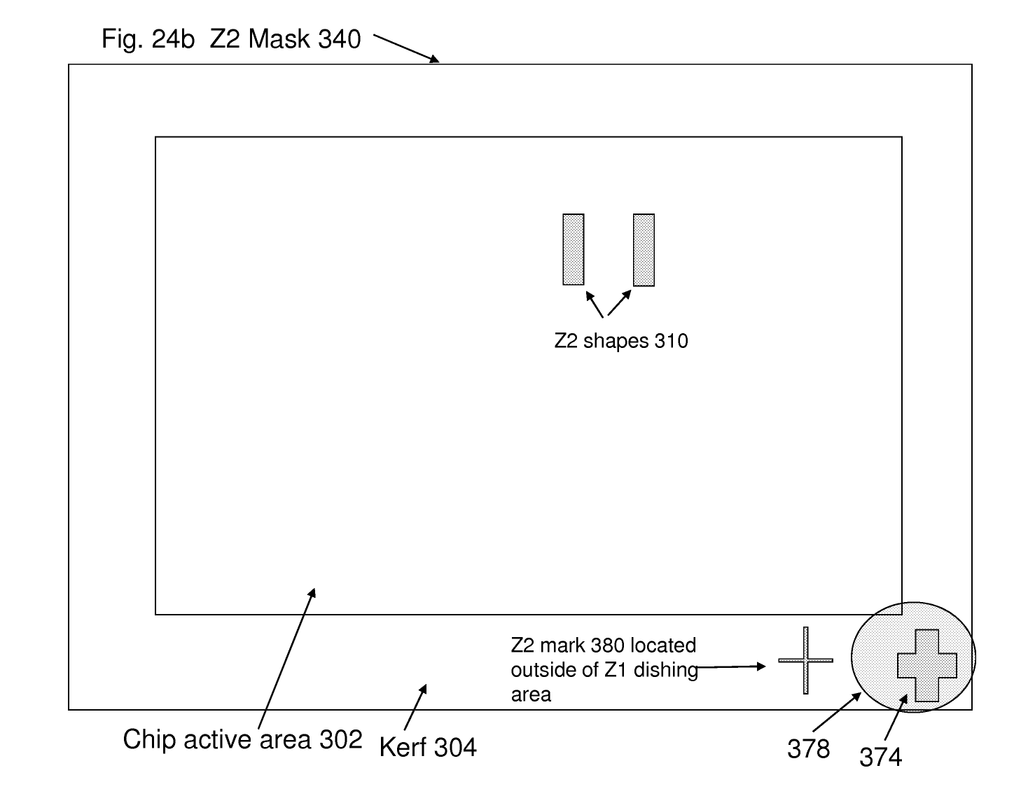

More specifically, in FIG. 23a, photomask 334 uses a sub-lithographic shape 374, and in FIG. 23b photomask 336 uses an sub-lithographic shape 376. Because of the proximity of shapes 374 and 376, a dishing area 378 will be present on the underlying substrate (e.g. 200) that is patterned using etching masks formed using photomasks 334 and 336. For example, polishing processes may be applied to the substrate 200 and the proximity of the alignment marks 374, 376 can cause the dishing 378 to occur. These dishing processes are disadvantageous because they can distort one or both of the alignment marks 374, 376. In view of this, as shown in FIG. 24a-24b (which illustrate photomasks 338, 340) the second photomask 340 utilizes an sub-lithographic shape 380 that is spaced sufficiently from the first sub-lithographic shape 374 so that dishing effects and are avoided.

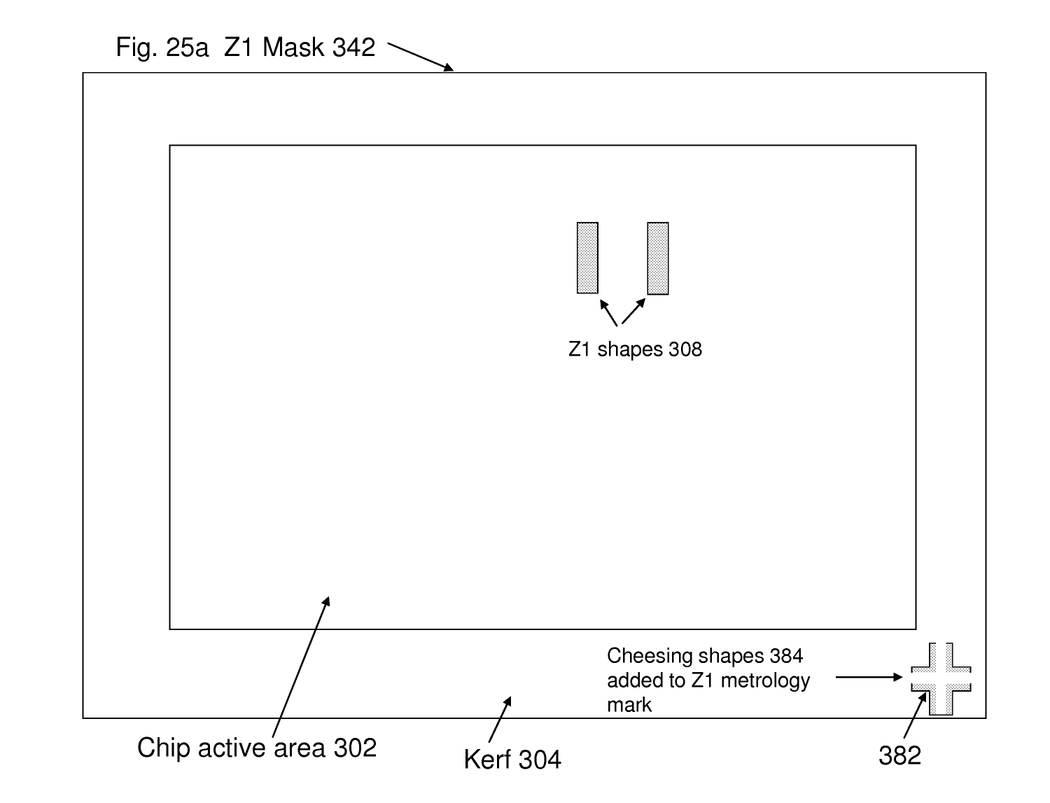

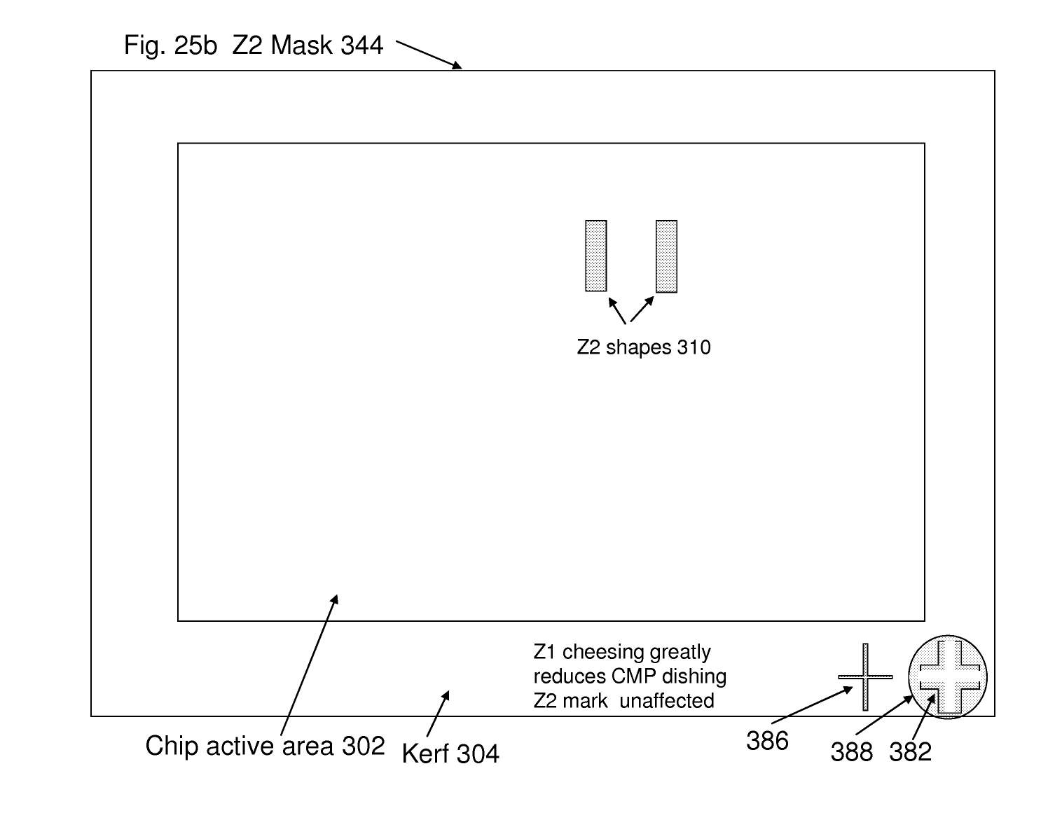

An additional embodiment that addresses the dishing issue is again a photomask 342 (illustrated in FIG. 25a) that comprises a light filter in an exposure system. In this embodiment, the features comprise one or more device shapes 308, 310 and at least one sub-lithographic shape 382, where the sub-lithographic shape 382 comprises an outline (or cheesing) shape. As shown in FIG. 25a, this “outline shape” 382 comprising at least two outline features separated from one another by a distance 384 smaller than sizes of the device shapes 308, 310. More specifically, the outline features 382 illustrated in FIG. 25a comprise four right-angle shaped outline features forming two crossing lines represented by the gaps 384 between the features 382. FIG. 25b illustrates how the outline shape 382 produces a smaller dishing area of 388 on the underlying substrate (e.g. 200) and how this dishing area 388 does not interfere with the subsequent sub-lithographic shape 386.

The method as described above is used in the fabrication of integrated circuit chips. Any resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A photomask that comprises a light filter in an exposure system, said photomask comprising:
at least one layer of material comprising one or more transparent regions and one or more non-transparent regions, a difference between said transparent regions and said non-transparent regions defining features that will be illuminated by said exposure system on a photoresist exposed using said exposure system,
said features comprising one or more device shapes and at least one sub-lithographic shape,
said sub-lithographic shape having an sub-lithographic shape size, and
said sub-lithographic shape size being limited such that said sub-lithographic shape causes a physical change only in a surface of said photoresist and such that said sub-lithographic shape avoids forming an opening through said photoresist after said photoresist is developed.

2. The photomask according to claim 1, said photoresist comprising an etching mask after said photoresist is developed, said device shapes being transferred to a second layer underlying said etching mask during an etching process that uses said etching mask, said sub-lithographic shape avoiding being transferred to said second layer based on said sub-lithographic shape size.

3. The photomask according to claim 1, said device shapes having one or more device shape sizes, said device shape sizes being large enough such that said device shapes form one or more openings through said photoresist after said photoresist is developed.

4. The photomask according to claim 1, said sub-lithographic shape size being smaller than all of said device shapes.

5. The photomask according to claim 1, said photomask comprising a device region and a kerf region surrounding said device region, said device shapes being positioned in said device region said sub-lithographic shape being positioned in at least one of said kerf region and said device region.

6. The photomask according to claim 1, said sub-lithographic shape being positioned a predetermined distance from other alignment marks on other photomasks relative to said exposure system, such that a position of said sub-lithographic shape avoids dishing effects from occurring with said adjacent sub-lithographic shapes in surfaces patterned and planarized using said photomasks.

7. A photomask that comprises a light filter in an exposure system, said photomask comprising:
at least one layer of material comprising one or more transparent regions and one or more non-transparent regions, a difference between said transparent regions and said non-transparent regions defining features that will be illuminated by said exposure system on a photoresist exposed using said exposure system,
said features comprising one or more device shapes and at least one sub-lithographic shape,
said sub-lithographic shape having an sub-lithographic shape size, and
said sub-lithographic shape size being limited such that said sub-lithographic shape causes a smaller physical change in said photoresist after said photoresist is developed relative to a change caused by said device shapes after said photoresist is developed.

8. The photomask according to claim 7, said device shapes having one or more device shape sizes, said device shape sizes being large enough such that said device shapes form one or more openings through said photoresist after said photoresist is developed.

9. The photomask according to claim 8, said photoresist comprising an etching mask after said photoresist is developed, said device shapes and said sub-lithographic shape being transferred to a second layer underlying said etching mask during an etching process that uses said etching mask, said device shape sizes causing deeper openings in said second layer relative to openings caused by said sub-lithographic shape size.

10. The photomask according to claim 7, said sub-lithographic shape size being smaller than all of said device shapes.

11. The photomask according to claim 7, said photomask comprising a device region and a kerf region surrounding said device region, said device shapes being positioned in said device region said sub-lithographic shape being positioned in said kerf region.

12. The photomask according to claim 7, said sub-lithographic shape being positioned a predetermined distance from other alignment marks on other photomasks relative to said exposure system, such that a position of said sub-lithographic shape avoids dishing effects from occurring with said adjacent sub-lithographic shapes in surfaces patterned and planarized using said photomasks.

13. A series of photomasks that comprise light filters in an exposure system, said series of photomasks comprising:
a first photomask comprising at least one first layer of material comprising one or more first transparent regions and one or more first non-transparent regions, a difference between said first transparent regions and said first non-transparent regions defining first features that will be illuminated by said exposure system on a photoresist exposed using said exposure system, said first features comprising one or more first device shapes and at least one first sub-lithographic shape, said first sub-lithographic shape having a first sub-lithographic shape size, and said first sub-lithographic shape size being limited such that said first sub-lithographic shape causes a physical change only in a surface of said photoresist and such that said first sub-lithographic shape avoids forming an opening through said photoresist after said photoresist is developed;
a second photomask to be exposed after said first photomask is exposed, second photomask comprising at least one second layer of material comprising one or more second transparent regions and one or more second non-transparent regions, a difference between said second transparent regions and said second non-transparent regions defining second features that will be illuminated by said exposure system on said photoresist exposed using said exposure system, said second features comprising and at least one blocking shape, said blocking shape being positioned at a different location than said first sub-lithographic shape relative to said exposure system; and
a third photomask to be exposed after said second photomask is exposed, said third photomask comprising at least one third layer of material comprising one or more third transparent regions and one or more third non-transparent regions, a difference between said third transparent regions and said third non-transparent regions defining third features that will be illuminated by said exposure system on said photoresist exposed using said exposure system, said third features comprising one or more third device shapes and at least one third sub-lithographic shape, said third sub-lithographic shape being positioned at the same location as said blocking shape relative to said exposure system.

14. The series of photomasks according to claim 13, said photoresist comprising an etching mask after said photoresist is developed, said first device shapes and said third device shapes being transferred to a fourth layer underlying said etching mask during an etching process that uses said etching mask, said first sub-lithographic shape avoiding being transferred to said fourth layer based on said sub-lithographic shape size.

15. The series of photomasks according to claim 13, said first device shapes and said third device shapes having one or more device shape sizes, said device shape sizes being large enough such that said device shapes form one or more openings through said photoresist after said photoresist is developed.

16. The series of photomasks according to claim 13, said first sub-lithographic shape size being smaller than a third sub-lithographic shape size of said third sub-lithographic shape.

17. The series of photomasks according to claim 13, said first photomask, said second photomask, and said third photomask each comprising a device region and a kerf region surrounding said device region, said first device shapes and said third device shapes being positioned in said device region said first sub-lithographic shape, said blocking shape, and said third sub-lithographic shape being positioned in said kerf region.

18. The series of photomasks according to claim 13, said first sub-lithographic shape being positioned a predetermined distance from said third alignment marks on other photomask relative to said exposure system such that a position of said first sub-lithographic shape avoids dishing effects from occurring with said third sub-lithographic shape in surfaces patterned and planarized using said third photomask.

19. The series of photomasks according to claim 14, said blocking shape forming a blocking feature on said fourth layer that prevents said third sub-lithographic shape from being patterned into said fourth layer.

20. A photomask that comprises a light filter in an exposure system, said photomask comprising:
at least one layer of material comprising one or more transparent regions and one or more non-transparent regions, a difference between said transparent regions and said non-transparent regions defining features that will be illuminated by said exposure system on a photoresist exposed using said exposure system,
said features comprising one or more device shapes and at least one sub-lithographic shape,
said sub-lithographic shape comprising an outline shape.

21. The photomask according to claim 20, said outline shape comprising at least two outline features, of said features, separated from one another by a distance smaller than sizes of said device shapes.

22. The photomask according to claim 21, said outline features comprising four outline features forming two crossing lines.

23. The photomask according to claim 20, said device shapes having one or more device shape sizes, said device shape sizes being large enough such that said device shapes form one or more openings through said photoresist after said photoresist is developed.

24. The photomask according to claim 20, said photomask comprising a device region and a kerf region surrounding said device region, said device shapes being positioned in said device region said sub-lithographic shape being positioned in said kerf region.

25. The photomask according to claim 20, said sub-lithographic shape being positioned a predetermined distance from other alignment marks on other photomasks relative to said exposure system, such that a position of said sub-lithographic shape avoids dishing effects from occurring with said adjacent sub-lithographic shapes in surfaces patterned and planarized using said photomask.
